(19) United States
(12) Patent Application Publication
(10) Pub. No.: US 2006/0105573 A1
(43) Pub. Date: May 18, 2006

(54) Method for selective plasma etch of an oxide layer

(75) Inventors: Pushpa Mahalingam, Richardson, TX (US); Bill A. Wofford, Dallas, TX (US)

Correspondence Address: TEXAS INSTRUMENTS INCORPORATED, P O BOX 655474, M/S 3999, DALLAS, TX, 75265, US

(73) Assignee: Texas Instruments, Inc., Dallas, TX (US)

(21) Appl. No.: 10/992,155

(22) Filed: Nov. 18, 2004

(51) Int. Cl. H01L 21/465

(52) U.S. Cl. 438/706; 438/738

(57) ABSTRACT

The present invention provides, in one embodiment, a method of forming an opening in a dielectric layer 150. In this embodiment, the method comprises forming a dielectric layer 150 over a target layer 130 located over a microelectronic substrate 110 and subjecting the dielectric layer 150 to a plasma etch 165 to form an opening 145 in the dielectric layer 150, wherein the plasma etch 165 is highly selective to the target layer 130, such that a selectivity of the dielectric layer 150 to the target layer 130 is at least about 18:1 and a dielectric etch rate of the plasma etch 165 is at least about 380 nm/min.

### TECHNICAL FIELD OF THE INVENTION

The present invention is directed in general to a method for etching a microelectronic substrate, and more specifically, to a method for conducting a plasma etch on an oxide layer that is highly selective to a target layer of an integrated circuit structure.

### BACKGROUND

As the overall size of integrated circuits (ICs) continues to shrink and performance and device product output demands increase, all aspects of the IC fabrication process becomes more complicated. For example, IC designs often include capacitor structures located at the pre-metal dielectric (PMD) layer and inter-metal dielectric (IMD) layers. The PMD is typically considered to be dielectric layer located between metal level 1 and the active device level, while the IMD is the dielectric layer between two metal levels. Often, these structures include electrodes comprising titanium nitride (TiN), titanium/tungsten (W) or tantalum nitride (TaN) layers. Problems arise during the oxide etch when the etch that is used to etch through the PMD layer to contact the device level, also etches into the top electrode of the capacitor. This occurs because, in most instances, these capacitors are stacked structures, and the top electrode is considerably topographically higher than the structures at the active device level, i.e. there is a wide variance in aspect ratios among contacts to gate, moat and capacitors. Thus, during the process of etching to the device level, the etch often proceeds an unacceptable distance into the top electrode of the capacitor. This is highly undesirable because it can deleteriously affect the operation of the capacitor or cause it to malfunction altogether.

In contending with this problem, conventional processes have used an etching plasma that either produces an unacceptable amount of polymer during the etch process or etches too slowly to achieve high volume device production. Both of these effects are less than ideal because a high production of polymer can cause plugging problems within the contact opening or via. This can result in partially blocked openings, completely blocked openings, or irregular or incompletely formed openings. When this occurs, proper filling of the opening is difficult if not impossible to achieve without additional process steps. A slow etch rate is also less than desirable because production time is significantly increased in etching through the oxide, which can be as much as 1500 nm thick, thereby decreasing device output. The present processes do not adequately address these problems.

In addition to those areas of the IC just discussed above, problems associated with conventional plasma etches also occur during the formation of via interconnects. Often anti-reflective coating (ARC) layers, such as titanium nitride (TiN), titanium, tantalum nitride (TaN) or tantalum are often used on underlying metal interconnect structures, such as aluminum or copper, respectively to overcome problems associated with lithographic techniques used to form the vias that contact such metal interconnects. Thus far in the semiconductor industry, via etch is not controlled to land vias in top of the thin, for example less than 50 nm, ARC layer using the conventional plasma chemistries. To this point, vias landing in underlying aluminum has been acceptable for non-reacting aluminum interconnect structures, such as TiN—Al—TiN or TiN—Al—Ti—TiN. As explained below, there is typically a reaction between barrier Ti and the Al metal stack. If the via lands in Al even for the non-reacting stacks, this can contribute to the formation of voids, and therefore, have deleterious affects on device performance. However for high electromigration (EM) performance interconnect metal stacks with reactive titanium aluminide layers, such as TiN—Ti—Al—Ti—TiN, it is essential to land vias in the thin top ARC layer, which may be any refractory metal nitride and ensure via reliability and via integrity. An additonal feature for landing vias in the top ARC layer is to minimize metal up-extrusion from the metal interconnect into the via. In the reactive aluminum stack, (i) Ti in the metal stack often reacts with Al, and (ii) barrier Ti reacts with Al when via penetrates into Al both of which result in the formation of voids. If the etch proceeds into the TiAlx interface or aluminum and contacts a void, subsequent barrier formation within the via is compromised and can lead to defective via formation within the IC.

Accordingly, what is needed in the art is an improved method for etching oxide that can efficiently etch through the oxide while allowing for a controlled landing on a thin target layer without suffering the disadvantages associated with the conventional processes discussed above.

### SUMMARY OF INVENTION

To address the above-discussed deficiencies of the prior art, the present invention provides, in one embodiment, a method of forming an opening in a dielectric layer. In this embodiment, the method comprises forming a dielectric layer over a target layer located over a microelectronic substrate and subjecting the dielectric layer to a plasma etch to form an opening in the dielectric layer, wherein the plasma etch is highly selective to the target layer, such that a selectivity of the dielectric layer to the target layer is at least about 18:1 and a dielectric etch rate of the plasma etch is at least about 380 nm/minute.

In another embodiment, the present invention provides a method for fabricating an integrated circuit. In this embodiment, the method comprises forming transistors on a microelectronics substrate, depositing a dielectric layer over a target layer located over the transistors, subjecting the dielectric layer to a plasma etch to form an opening in the dielectric layer, wherein the plasma etch is highly selective to the target layer, such that a selectivity of the dielectric layer to the target layer is at least about 18:1 and a dielectric etch rate of the plasma etch is at least about 380 nm/minute, placing a metal within the opening to form an interconnect, and interconnecting the transistors to form an operative integrated circuit.

The foregoing has outlined preferred and alternative features of the present invention so that those of ordinary skill in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the scope of the invention.

### BRIEF DESCRIPTION OF THE DRAWINGS

The invention is best understood from the following detailed description when read with the accompanying Figs. It is emphasized that in accordance with the standard practice in the semiconductor industry, various features may not be drawn to scale. In fact, the dimensions of the various features may be arbitrarily increased or reduced for clarity of discussion. Reference is now made to the following descriptions taken in conjunction with the accompanying drawings, in which:

FIG. 1 illustrates a sectional view of a microelectronics device, as provided by an embodiment of the present invention, at an intermediate point of manufacture;

FIG. 2A, illustrates a sectional view of a microelectronics device showing a metal level that can be manufactured in accordance with the principles of the present invention;

FIG. 2B, is an enlarged isolated partial sectional view of one of the interconnects of FIG. 2A formed in accordance with the principles of the present invention;

FIG. 3 is an enlarged isolated partial sectional view of an interconnect fabricated by conventional process illustrating how the via opening intersects voids within the metal line; and

FIG. 4. is a sectional view of an integrated circuit that can be fabricated using the principles of the present invention.

### DETAILED DESCRIPTION

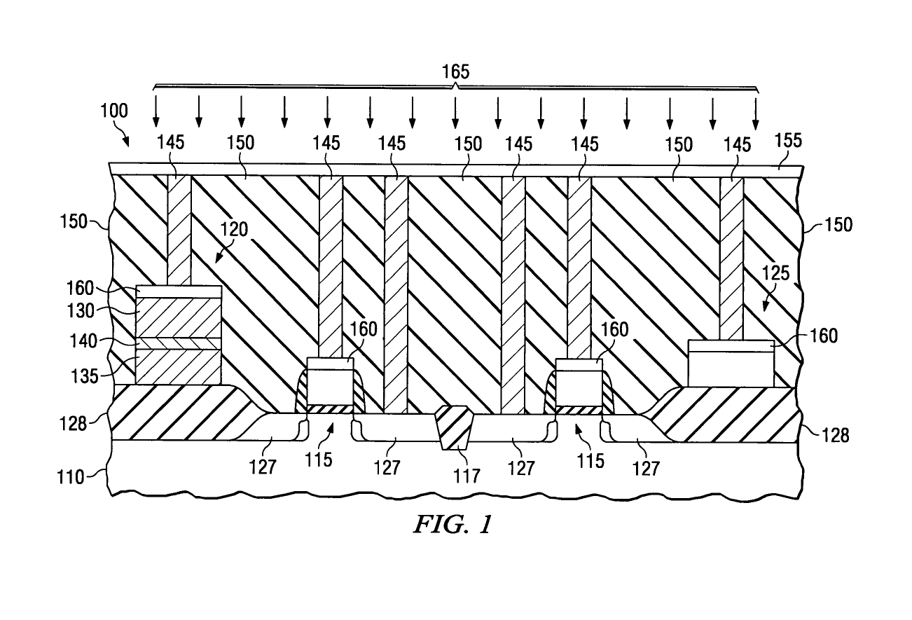

Turning initially to FIG. 1, there is illustrated a sectional view of a microelectronics device 100, as provided by an embodiment of the present invention, at an intermediate point of manufacture. At the outset, it should be noted that the present invention may be employed at any level within the microelectronics device 100 to form interconnects and may be used to form either contacts or vias to contact a device at any level within the microelectronics device 100. In the exemplary embodiment shown in FIG. 1, the formation is taking place at the contact level, but the present invention is also applicable to back end processes, including a metal to metal capacitor in the inter metal dielectric layer. The microelectronics device 100 includes a substrate 110, examples of which include semiconductive substrates, such as doped silicon, silicon-germanium or gallium arsenide. However, other materials that can be employed to build microelectronic devices may also be used. This embodiment also includes conventionally formed transistors 115 located on the substrate 110, which are isolated by isolation structure 117 and a conventionally formed capacitor 120 and poly gate 125, both of which are located on field oxides 128. The capacitor 120 includes a target layer 130, which here, is the upper electrode of the capacitor 120. In this structure, the target layer 130 may have a thickness of about 200 nm. The composition of the target layer 130 will vary depending on the structure that is being contacted. For example, the target layer 130 may comprise a metal or nitride, such as a metal, metal nitride or a non-metal nitride. For example and depending on design, the target layer 130 may be TiN, TaN, or it may comprise a stack of metals, such as TiN and Ti/W or Ta/TaN or a non-metal nitride such as silicon nitride. These are exemplary in nature only, and it should be understood that other metals or metal compounds used to form such capacitors may also be used. The capacitor 120 further comprises a second electrode 135, such as a doped polysilicon material or a metal, which may have a thickness of about 300 nm and is electrically insulated from the target layer 130 by dielectric layer 140.

As generally seen in the schematically illustrated embodiment, the heights of the tops of both the capacitor 120 and the polysilicon gate 125 are considerably higher than the top surfaces of the transistors 115 or the source/drain or moat regions 127 formed in the substrate 110. It is this difference in height to width or aspect ratios that can present problems during the formation of openings 145. A conventionally formed dielectric layer 150, examples of which may include phosphorous silica glass (PSG) oxide, boron phosphorous silica glass (BPSG) oxide, high density plasma (HDP) oxide, or tetraorthosilicate glass (TEOS) oxide, is shown located over the transistors 115, the capacitor 120 and the poly gate 125. The amount of dielectric layer 150 through which the etch is to be conducted will, of course, depend to a certain extent on the structure over which the dielectric layer 150 is deposited and the thickness of any other dielectric materials present. For example in some designs, the dielectric layer 150 may have an etch thickness ranging from about 250 nm that is located over the capacitor 120, to about 920 nm that is located over the transistors 115, to about 1300 nm that is located over the moats 127, and to about 460 nm that is located over the poly gate 125.

In addition, however a 100 nm TEOS cap layer 155 may be located on top of the dielectric layer 150. Similarly, a 50 nm TEOS or silicon nitride cap 160 may be located on top of the transistors 115. Thus, the etching distance to the top of the target layer, which in the illustrated embodiment is the electrode 130 of the capacitor 120, may be about 400 nm, or less, whereas the etching distance to the top of the transistors 115 and the poly gate 125 may be about 1,070 nm and 610 nm, respectively. As seen from this figure, during an etch 165 of the dielectric layer 150, the etch 165 will contact the electrode 130 much sooner than it contacts the top of the transistors 115. If the etch 165 is not highly selective to the electrode 130, it may proceed into the electrode 130 unacceptable distance, which could result in a defective device.

Further, due to this difference in etch distance, the aspect ratios (height to width) of the opening 145 formed over the respective structures will vary substantially across the microelectronics device 100, and in certain embodiments may range from about 1.33 up to 5, with 3 to 4.5 being expected in most applications. For instance, the aspect ratio of the opening 145 over the capacitor 120 may be about 1.33, while the aspect ratio of the opening 145 over the transistors 115 may range from about 3 to 4.5, and the aspect ratio of the opening 145 over the poly structure 125 may be about 2. Therefore, it is apparent that it is highly desirable to provide a controlled etch process that will quickly etch through bulk of the thickness of the dielectric 150 while effectively stopping on the target electrode 130. The present invention provides such a process.

With continued reference to FIG. 1, the dielectric layer 150 is conventionally patterned with a photoresist, which is not shown, and the plasma etch, 165, represented by the arrows, is conducted to form openings 145 in the dielectric layer 150. As mentioned above, this chemistry can be used to form openings with an aspect ratio as large as about 5:1 Preferably, the plasma etch 165 is highly selective to the target electrode 130 with which it comes into contact such that it either lands on top of the electrode 130 or does not excessively etch into the electrode 130. As mentioned above, the target layer might comprise Ti, TiN, Ta, TaN, W or any combination of these. In some applications, the target layer will be TiN. Other metals, however, that are used or could be used in the fabrication of microelectronic devices are also within the scope of the present invention.

In an advantageous embodiment, the selectivity of the dielectric layer 150 to the target layer is at least about 18:1, and a dielectric etch rate of the plasma etch 165 through the dielectric layer 150 is at least about 380 nm/minute. Depending on the embodiment, the etch rate can range from about 380 nm/min. to about 550 nm/per min. These unique characteristics offer an etch that not only provides a controlled etch with respect to the target layer, but also provides an etch that quickly and efficiently etches through the considerably thicker portions of the dielectric layer 150. By using the highly selective etch as provided herein, landing the via or contact in or on the top of the target layer 130 can be accomplished repeatedly and reliably, which in turn ensures repeatable and reliable connection for the high precision capacitors with better capacitor matching, lower noise, and better device performance.

In an exemplary embodiment, the plasma etch 165 uses a low polymerizing gas mixture. Due to the lower polymer forming characteristics of this chemistry, very high aspect ratio openings 145 of approximately 5:1, and perhaps even greater, can be achieved. In an advantageous embodiment, the gas mixture comprises an etching gas component, wherein the etching gas component is C₄F₈, CF₄, or C₅F₈. In addition, the gas mixture in this particular embodiment further comprises CO (carbon monoxide), O₂, and a carrier gas, such as argon or helium. The flows of the respective gases may vary somewhat, and they can be configured to permit a single or multi-level dielectric layer to be etched completely and without etching through the relatively thin target layer. However, it should be appreciated that different etching results can be achieved by changing the flow. For example lowering the O₂ can result in etch stop conditions for deep contact (i.e., those greater than about 1400 nm) while increasing the O₂ may lower the dielectric to metal etch rate from 23:1 to 10:1. On the other hand, lowering the CO flow by 10% can cause the sidewall profile of the opening 145 to be more tapered by about 1 degree, which might not be suitable for a deep contact, as it can cause contact resistance to increase.

Preferably, the flow rate of the etching gas ranges from about 12 sccm to about 15 sccm, while the flow rate of the CO ranges from about 160 sccm to about 240 sccm. The flow rate of the O₂ ranges from about 2 sccm to about 4 sccm and the flow rate of the carrier gas ranges from about 400 sccm to about 600 sccm.

In a more specific embodiment, the etching gas is C₄F₈ and has a flow rate of about 14 sccm with the flow rate of CO being about 200 sccm. The flow rate of O₂ is preferably about 3 sccm, and the flow rate of the carrier gas is about 550 sccm. This specific embodiment, provides a plasma etch 165 that has a HDP:TiN selectivity of about 30:1 and a HDP etch rate of about 500 nm/min. with a less than 3% etch rate non-uniformity. It should be understood that the gas flow discussed above may are tool dependent and may vary from one etching tool to another. However, given the teachings set forth herein, one skilled in the art would understand how to go about adjusting the gas flows specific to any given etching tool.

Regarding the plasma process parameters, given the teachings herein, one skilled in the art would be able to adjust the plasma chamber conditions to achieve the desired etching conditions. For example, the pressure of the chamber may be about 65 milli Torr (mT) with the backside helium pressure being about 40 T. The upper and lower electrode temperatures may be 60 and 15 degrees centigrade, respectively, and the power may be about 1700 watts. Again, it should be understood that these parameters may vary, depending on the tool being used.

In another aspect, the method further comprises conducting a plasma clean step subsequent to forming the opening 145 as described above. This clean step can be used to ash the polymer formed during the formation of the openings 145. While, the chemistries covered by the embodiments discussed above desirably exhibit low polymer forming properties, some polymer is nevertheless formed. In such instances, it is highly desirable that it be removed. This clean step is exemplary in nature only, and it should be understood that other polymer removing chemistry/processes may also be used to remove the polymer. In one advantageous embodiment, however, the plasma clean step comprises using a gas mixture including Ar and SF₆, wherein a flow rate of the Ar is about 300 sccm and a flow of SF₆ is about 50 sccm. Plasma chamber conditions can include a power setting of about 1700 watts, a chamber pressure of about 40 T and upper and lower electrode temperatures may be 60 C and 15 C, respectively.

An additional wet clean may also be conducted following the ashing step to remove the ash residue and other contaminants from within the opening. This additional clean step is conventional and is well known to those skilled in the art. For example, the wet clean may consist of a mixture of ammonium hydroxide, hydrogen peroxide and water. Preferably, a volumetric ratio of ammonium hydroxide to hydrogen peroxide to water is about 1:1:10. To remove the ashed photoresist and conduct the subsequent clean, the microelectronics device 100 is advantageously exposed to the wet etch for a period of time ranging from about 1 minute to about 7 minutes and at a temperature ranging from about 60 C to about 130 C. It should be understood that other wet cleans known to those skilled in the art may also be used and the present invention is not limited to the use of any particular wet clean.

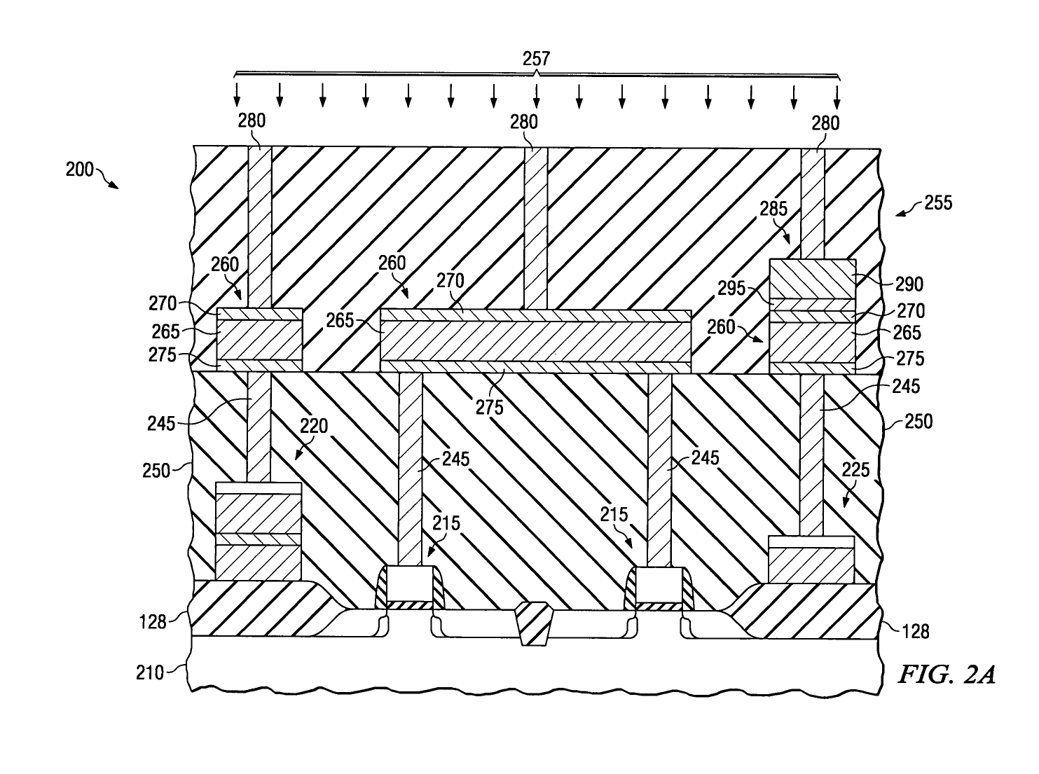

Turning now to FIG. 2A, illustrated is a sectional view of a microelectronics device 200 showing a metal level 255 therein. As mentioned above, the plasma etch 257 of the present invention can be used at any level within the microelectronics device 200, and as such, may also be used to form other openings such as vias, to make interconnects within the various dielectric levels within the microelectronics device 200. As seen in FIG. 2A, the microelectronics device 200 includes a substrate 210, such as a conductive substrate, examples of which include those previously discussed. This embodiment also includes conventionally formed transistors 215 located on the substrate 210 and a conventionally formed capacitor 220 and poly structure 225 located on field oxides 228, all of which are discussed above with respect to FIG. 1. Contacts 245 are formed in a dielectric layer 250, similar to those discussed above, and they interconnect the transistors 215, the capacitor 220 and the poly structure 225 by way of the overlying metal level 255. The metal level 225 comprises metal interconnects 260 that each include metal lines 265 having an upper metal barrier layer 270 and a lower metal barrier layer 275. The upper and lower metal barrier layers 270, 275 may be either a single layer or a stack. For example, in those instances where the metal line 265 comprises aluminum, the upper metal barrier 270 may be TiN or may be a TiN/Ti stack with the lower metal barrier layer being Ti. Alternatively, in those instances where the metal line 265 comprises copper, the upper metal barrier layer may be TaN or TaN/Ta with the lower metal barrier layer being Ta. Vias 280 contact the upper barrier layers 270 of the metal lines 265 and connect the metal lines 265 to upper layers, which are not shown. In addition a conventional metal to metal capacitor 285, comprising an upper metal electrode 290 and dielectric layer 295, might be located over one of the metal lines 265, as illustrated. As previously mentioned, the present process can be used to contact the capacitor 285 as well.

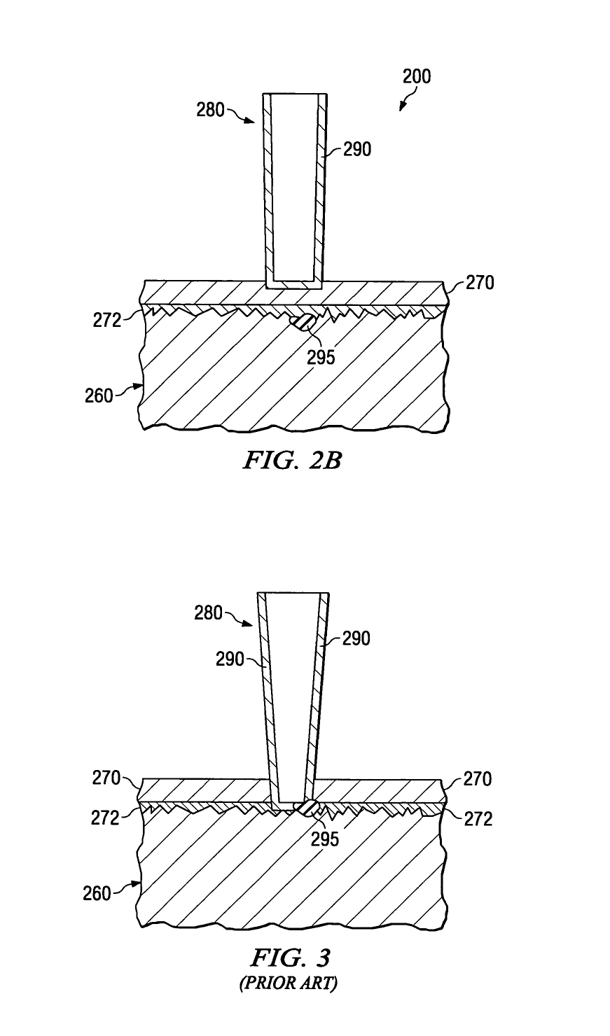

Referring now to FIG. 2B, there is shown an enlarged isolated partial view of one of the interconnects 260 of FIG. 2A formed in accordance with the principles of the present invention. The etch 257 can be used to form such interconnects because it is highly advantageous to have the ability to etch through a significant thickness of dielectric while maintaining reliable via landing control. The reason for this stems primarily from the presence of interacting metals in the interconnects 260. For instance, in many applications, aluminum is used to form the metal line 265. In such instances the upper barrier layer 270, which is typically comprised of TiN or a metal stack of TiN/Ti, is deposited on top of the aluminum. When these metals are present and in contact with each other, titanium aluminide (TiAlₓ) layer 272 can form. If the dielectric etch proceeds too far into the upper layer 270, as shown in FIG. 3, as occurs with prior art process, this can result in the absence of the barrier layer 290 in the lower portion of the via 280 due to the difficulty in forming the barrier layer on such an uneven surface. This, in turn, leaves the via 280 open for tungsten hexafluoride attack during the tungsten filling step and can result in void 295 formation and a defective via.

In contrast to the results shown in FIG. 3, which occurs with prior art process, the present process provides sufficient control for etching the via 280 due to the selectivity of the etch chemistry. Thus, the via 280 is purposely and reproducibly landed on the upper thin ARC layer 270 such that it does not come into contact with the titanium aluminide layer 272, and thus, the void 295. As a result, the problems associated with void formation and metal extrusion associated with prior art process is thereby avoided. It should also be noted in comparing the two schematic figures that the present process also provides for a straighter opening wherein the angle of the sidewalls is about 88 degrees over the more slanted prior art configuration. The straighter profile enables excellent fill to provide good contacts at the bottom of the via or contact for very high aspect ratios.

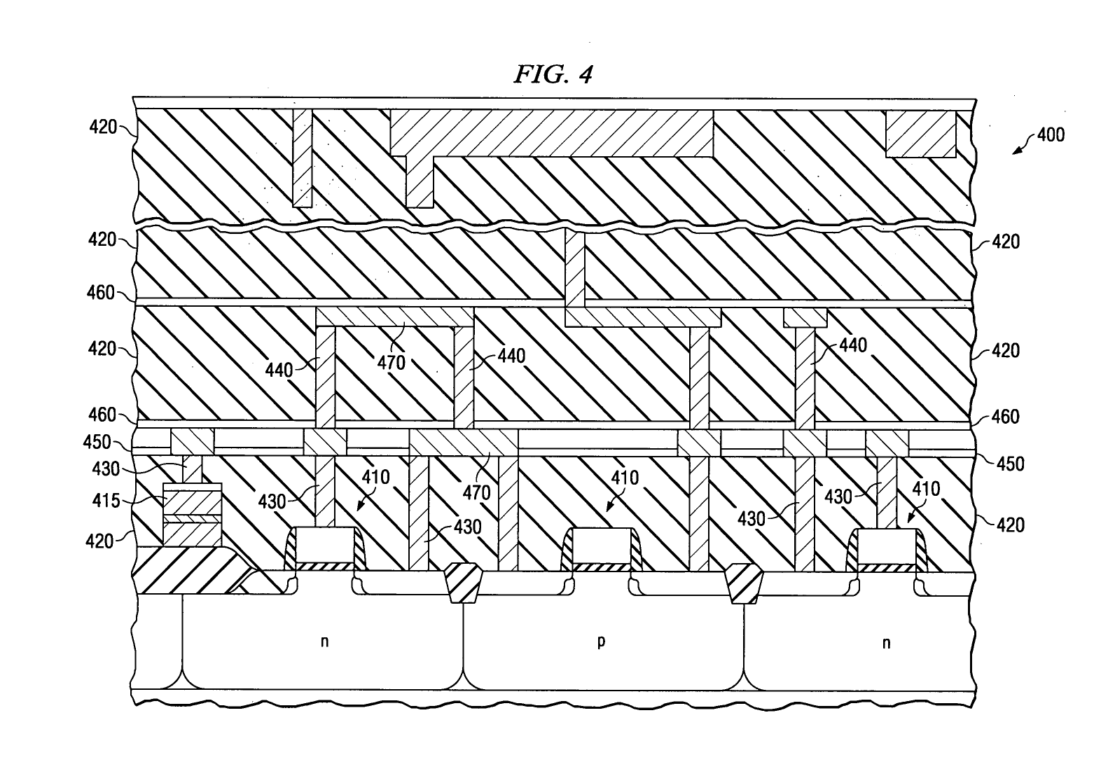

Referring finally to FIG. 4, illustrated is a cross-sectional view of an integrated circuit (IC) 400 incorporating transistors 410, and capacitor 415 interconnected by contacts 430, vias 440, and metal lines 470, which can be fabricated as discussed above. The vias 440 and metal lines 470 are embedded in conventionally deposited dielectric 420, which may be single or multilayered, using one or more dielectric materials, as noted herein. Diffusion barrier 460 overlies dielectric 420 and metal lines 470, and may comprise conventionally deposited silicon nitride, silicon carbide, or other suitable dielectric material. At least one level of dielectric 420 has been processed according to the principles of the current invention to produce openings in which metal is placed for vias 440 and/or metal lines 470. The IC 400 may include devices, such as transistors 410 used to form CMOS devices, BiCMOS devices, bipolar devices, capacitors or other types of devices.

The IC 400 may further include passive devices, such as capacitors, as shown in FIG. 1, inductors or resistors, or it may also include optical devices or optoelectronic devices. Those skilled in the art are familiar with these various types of devices and their manufacture. Metal lines 470 and vias 440 are used to connect the various devices to form the operational IC 400. The interconnect architecture of the IC 400 is exemplary of one that may be fabricated according to the principles of the invention. It will be apparent to one skilled in the art that several variations of the exemplary interconnect architecture may be fabricated according to the principles of the invention with similarly advantageous results.

Although the present invention has been described in detail, one who is of ordinary skill in the art should understand that they can make various changes, substitutions, and alterations herein without departing from the scope of the invention.

What is claimed is:

1. A method of forming an opening in a dielectric layer, comprising:
forming a dielectric layer over a target layer located over a microelectronic substrate; and
subjecting the dielectric layer to a plasma etch to form an opening in the dielectric layer, wherein the plasma etch is highly selective to the target layer, such that a selectivity of the dielectric layer to the target layer is at least about 18:1 and a dielectric etch rate of plasma etch is at least about 380 nm/minute.

2. The method as recited in claim 1, wherein the selectivity is at least about 23:1.

3. The method as recited in claim 1 wherein the target layer forms a portion of a microelectronics device and comprises metal or nitride.

4. The method as recited in claim 3, wherein the metal is titanium or tantalum and the nitride is titanium nitride, tantalum nitride, silicon nitride or a combination thereof, and the portion is a capacitor or an interconnect structure.

5. The method as recited in claim 1, wherein subjecting comprises forming an opening in the dielectric layer having an aspect ratio of at least about 3.0.

6. The method as recited in claim 1 wherein subjecting includes using a low polymerizing gas mixture comprising an etching gas wherein the etching gas is C₄F₈, CF₄, or C₅F₈.

7. The method as recited in claim 6 wherein the gas mixture further comprises CO, O₂, and a carrier gas.

8. The method as recited in claim 7 wherein a flow rate of the etching gas ranges from about 12 sccm to about 15 sccm, a flow rate of the CO ranges from about 160 sccm to about 240 sccm and a flow rate of the O₂ ranges from about 2 sccm to about 4 sccm.

9. The method as recited in claim 1 further comprising conducting a plasma clean step subsequent to forming the opening, wherein the plasma clean step comprises using a gas mixture including Ar and SF₆, wherein a flow rate of the Ar is about 500 sccm and a flow of SF₆ is about 50 sccm.

10. The method as recited in claim 1 wherein the dielectric etch rate of the plasma ranges from about 380 nm/min. to about 550 nm/per min.

11. A method for fabricating an integrated circuit, comprising:
forming transistors on a microelectronics substrate;
depositing a dielectric layer over a target layer located over the transistors;
subjecting the dielectric layer to a plasma etch to form an opening in the dielectric layer, wherein the plasma etch is highly selective to the target layer, such that a selectivity of the dielectric layer to the target layer is at least about 18:1 and a dielectric etch rate of plasma etch is at least about 380 nm/minute;
placing a metal within the opening to form an interconnect; and
interconnecting the transistors to form an operative integrated circuit.

12. The method as recited in claim 11, wherein the selectivity is at least about 23:1.

13. The method as recited in claim 11 wherein the target layer forms a portion of a microelectronics device and comprises a metal or nitride.

14. The method as recited in claim 13, wherein the metal it titanium or tantalum and the nitride is titanium nitride, tantalum nitride, silicon nitride or combinations thereof and the portion is a capacitor or an interconnect structure.

15. The method as recited in claim 14, wherein the capacitor structure includes an electrode comprising titanium, nitride or tungsten, and the interconnect structure is aluminum having a target layer located thereon comprising titanium and nitride, or the interconnect structure is copper having a metal containing layer located thereon comprising tantalum and nitride.

16. The method as recited in claim 11 wherein subjecting comprises using a low polymerizing gas mixture including an etching gas wherein the etching gas is C₄F₈, CF₄, or C₅F₈.

17. The method as recited in claim 16 wherein the gas mixture further includes CO, O₂, and a carrier gas.

18. The method as recited in claim 17 wherein a flow rate of the etching gas ranges from about 12 sccm to about 15 sccm, a flow rate of the CO ranges from about 160 sccm to about 240 sccm and a flow rate of the O₂ ranges from about 2 sccm to about 4 sccm.

19. The method as recited in claim 11 further comprising conducting a plasma clean step subsequent to forming the opening, wherein the plasma clean step includes using a gas mixture comprising Ar and SF₆, wherein a flow rate of the Ar is about 500 sccm and a flow of SF₆ is about 50 sccm.

20. The method as recited in claim 11 wherein a dielectric etch rate of the plasma ranges from about 380 nm/min. to about 550 nm/per min.
